(19) United States
(12) Patent Application Publication
(10) Pub. No.: US 2026/0090064 A1
(43) Pub. Date: Mar. 26, 2026

(54) GATE CONTACT STRUCTURES IN SEMICONDUCTOR DEVICES

(71) Applicant: Taiwan Semiconductor Manufacturing Company, Ltd., Hsinchu (TW)

(72) Inventors: Man-Nung SU, Taipei City (TW); Chen-Luo Cheng, Taipei City (TW); Po-Chin Chang, Taichung City (TW); Peng-Hsuan Chiang, Hsinchu City (TW); Huan-Chieh Su, Tianzhong Township (TW); Sung-Li Wang, Zhubei City (TW); Chih-Hao Wang, Baoshan Township (TW); Pinyen Lin, Rochestar, NY (US)

(73) Assignee: Taiwan Semiconductor Manufacturing Company, Ltd., Hsinchu (TW)

(21) Appl. No.: 18/891,949

(22) Filed: Sep. 20, 2024

(51) Int. Cl. H01L 29/49; H01L 21/8238; H01L 27/092; H01L 29/06; H01L 29/417; H01L 29/423; H01L 29/66; H01L 29/775; H01L 29/786

(52) U.S. Cl. CPC H10D 64/666; H10D 30/014; H10D 30/43; H10D 30/6729; H10D 30/6735; H10D 30/6757; H10D 62/121; H10D 64/667; H10D 84/0172; H10D 84/038; H10D 84/85

(57) ABSTRACT

This disclosure is directed to a structure of a semiconductor device and a method of forming the structure. The structure includes a gate contact structure on a gate structure of a transistor. The gate contact structure includes a metal via through a dielectric layer and in contact with a gate electrode of the gate structure. The metal via includes a metal with a low value of a product of resistivity and a mean free path, such as ruthenium. An interface between the metal via and the gate electrode is oxygen free.

### BACKGROUND

With advances in semiconductor technology, there has been increasing demand for higher storage capacity, faster processing systems, higher performance, and lower costs. To meet these demands, the semiconductor industry continues to scale down the dimensions of semiconductor devices, such as metal oxide semiconductor field effect transistors (MOSFETs), including planar MOSFETs, fin field effect transistors (finFETs), and gate-all-around field effect transistors (GAA FETs). Such scaling down has increased the complexity of semiconductor manufacturing processes.

### BRIEF DESCRIPTION OF THE DRAWINGS

Aspects of the present disclosure are best understood from the following detailed description when read with the accompanying figures. It is noted that, in accordance with the common practice in the industry, various features are not drawn to scale. In fact, the dimensions of the various features may be arbitrarily increased or reduced for clarity of illustration and discussion.

FIG. 1 is an isometric view of a semiconductor device including semiconductor transistors, in accordance with some embodiments.

FIG. 2 is a cross-sectional view of a semiconductor device including semiconductor transistors, in accordance with some embodiments.

FIG. 3 is a cross-sectional view of a zoomed-in region of a semiconductor transistor including a gate contact structure, in accordance with some embodiments.

FIG. 4 is a flowchart of a method for the formation of a gate contact structure of a semiconductor transistor, in accordance with some embodiments.

FIGS. 5 and 6 are isometric views of intermediate structures during the fabrication of a gate contact structure of a semiconductor transistor, in accordance with some embodiments.

FIGS. 7 through 18 and 20 through 23 are cross-sectional views of intermediate structures during the fabrication of a semiconductor transistor, in accordance with some embodiments.

FIG. 19 is a diagram of a mass loading during an atomic layer cleaning process to clean an opening of a semiconductor structure, in accordance with some embodiments.

Illustrative embodiments will now be described with reference to the accompanying drawings. In the drawings, like reference numerals generally indicate identical, functionally similar, and/or structurally similar elements.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over a second feature in the description that follows may include embodiments in which the first and second features are formed in direct contact, and may also include embodiments in which additional features may be formed that are between the first and second features, such that the first and second features are not in direct contact. As used herein, the formation of a first feature on a second feature means the first feature is formed in direct contact with the second feature. In addition, the present disclosure may repeat reference numerals and/or letters in the various examples. This repetition does not in itself dictate a relationship between the various embodiments and/or configurations discussed.

Further, spatially relative terms, such as “beneath,” “below,” “lower,” “above,” “upper” and the like, may be used herein for case of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In some embodiments, the terms “about” and “substantially” can indicate a value of a given quantity that varies within 5% of the value (e.g., ±1%, ±2%, ±3%, ±4%, ±5% of the value). These values are merely examples and are not intended to be limiting. It is to be understood that the terms “about” and “substantially” can refer to a percentage of the values as interpreted by those skilled in relevant art(s) in light of the teachings herein.

It is noted that references in the specification to “one embodiment,” “an embodiment,” “an example embodiment,” “exemplary,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to effect such feature, structure or characteristic in connection with other embodiments whether or not explicitly described.

It is to be understood that the phraseology or terminology herein is for the purpose of description and not of limitation, such that the terminology or phraseology of the present specification is to be interpreted by those skilled in relevant art(s) in light of the teachings herein.

By way of example and not limitation, nanostructure transistors, like GAA nano-sheet (NS) or nano-wire (NW) FETs (collectively referred to as “GAAFETs”) with nano-sheet (NS) or nano-wire (NW) channel regions, can be formed as follows. A fin-like structure with alternating silicon-germanium (SiGe) and silicon (Si) NS or NW layers is formed on a substrate (e.g., on semiconductor substrate). A sacrificial gate structure is then formed on a middle portion of the fin-like structure to cover top and sidewall surfaces of the fin-like structure so that edge portions of the fin-like structure are not covered by the sacrificial gate structure. The edge portions of the fin-like structure not covered by the sacrificial gate structure are removed. Subsequently, edge portions of the SiGe NS or NW layers are recessed with respect to edge portions of the Si NS or NW layers, and an inner spacer structure is formed by depositing a dielectric material to fill the space formed by the etched portions of the SiGe NS or NW layers. Source/drain (S/D) epitaxial structures are then formed to abut (or to be in contact with) edge portions of the fin-like structures so that the S/D epitaxial structures are in contact with the Si NS or NW layers and isolated (or separated) from the SiGe NS or NW layers by the inner spacer structures. Source/drain may refer to a source or a drain, individually or collectively dependent upon the context. In a subsequent operation, the sacrificial gate structure is removed to expose the top and sidewall surfaces of the fin-like structure. The SiGe NS or NW layers are selectively removed from the fin-like structure. During the selective removal process, the Si NS or NW layers and the inner spacer structures are not removed. Subsequently, a metal gate structure is formed to surround the Si NS or NW layers. Similar to the SiGe NS or NW layers prior to their selective removal, the metal gate structure is isolated (or separated) from the S/D epitaxial structures through the inner spacer structures.

The structure of the GAAFETs may be patterned by any suitable method. For example, the structures may be patterned using one or more photolithography processes, including double-patterning or multi-patterning processes. Double-patterning or multi-patterning processes can combine photolithography and self-aligned processes, allowing patterns to be created that have, for example, pitches smaller than what is otherwise obtainable using a single, direct photolithography process. For example, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA transistor structure.

As semiconductor devices continue scaling down, in the exemplary GAAFET formed by the process described above, critical dimensions of the GAAFET, such as lengths/widths of the Si NS or NW layers as channels and the metal gate structure are getting smaller. Accordingly, the formation of a gate contact via through a dielectric layer above the metal gate structure becomes more challenging, as higher aspect ratio (a ratio of a depth to a width) of the gate contact via is necessary for effective electrical coupling with the metal gate structure with the smaller critical dimension. For example, once the width of gate contact via is scaled down to around 10 nm or below, the conductive performance of the gate contact via becomes significantly affected by not only the resistivity of the metal used for the gate via but also the electron mean free path in the metal. Compared with other materials for the gate via, such as tungsten (W), other materials with lower values of a product of the resistivity and the electron mean free path may yield better conductive performance. Also, a smaller metal gate structure provides a smaller contact interface between the gate contact via and the metal gate structure, and the quality of their contact interface becomes more critical in affecting the conductive performance. During the formation of the gate contact via, an oxide layer may be formed at a top surface of the metal gate structure when etching a dielectric layer above to form a narrow opening for the gate contact via. The presence of such an oxide layer at the contact interface may become a bottleneck of the conductive performance. Further, within the narrow opening through the dielectric layer, forming high-quality gate vias can be difficult since the metal deposited on dielectric side surfaces of the opening can form overhang and/or early merging structures during the deposition, introducing defects, void, and/or discontinuities in the gate via and compromising its conductive performance.

The embodiments described herein are directed to overcome the challenges mentioned above. In some embodiments, a structure of a semiconductor device can include a dielectric layer on a field effect transistor. The structure can further include a gate contact structure through the dielectric layer and in contact with a gate structure of the field effect transistor. The gate contact structure can include a metal via in contact with a gate electrode of the gate structure. The metal via can include a metal with a low value of a product of resistivity and electron mean free path, such as ruthenium. An interface between the metal via and the gate electrode can be oxygen free. The gate contact structure can further include a passivation layer between the metal via and the dielectric layer. In some embodiments, a method of forming the structure can include forming an opening through the dielectric layer to expose a top surface of the gate electrode and cleaning the top surface of the gate electrode to remove an oxide layer at the top surface of the gate electrode. The method can further include forming a layer of small molecule inhibitor (SMI) at the top surface of the gate electrode, forming the passivation layer on dielectric side surfaces of the opening, removing the layer of SMI, and deposit the metal via in the opening. The passivation layer can prevent the deposition of the metal on the dielectric side surfaces of the opening to avoid the formation of defects, voids, and/or discontinuities.

Regarding the selection of the metal for the gate contact via, below is a table including resistivity (ρ) and electron mean free path (λ) of several metal materials. Despite their relatively low values of ρ, metals, such as copper (Cu), molybdenum (Mo), and tungsten (W), may be less suitable for gate contact via with small critical dimensions and high aspect ratios, due to their relatively large values of λ. A comparison of the products ρ·λ among the metal materials shows that ruthenium (Ru), cobalt (Co), or iridium (Ir) may be better material candidates.

| | Copper | Cobalt | Tungsten | Molybdenum | Ruthenium | Iridium |
|---|---|---|---|---|---|---|
| | (Cu) | (Co) | (W) | (Mo) | (Ru) | (Ir) |
| Resistivity | 1.68 | 6.2 | 5.3 | 5.3 | 7.9 | 5.2 |
| (ρ [μΩ · cm]) | | | | | | |
| Mean free | 39.9 | 7.77 | 15.5 | 11.2 | 4.8 | 7.1 |
| path (λ [nm]) | | | | | | |
| ρ · λ [μΩ · um²] | 670 | 482 | 820 | 599 | 381 | 369 |

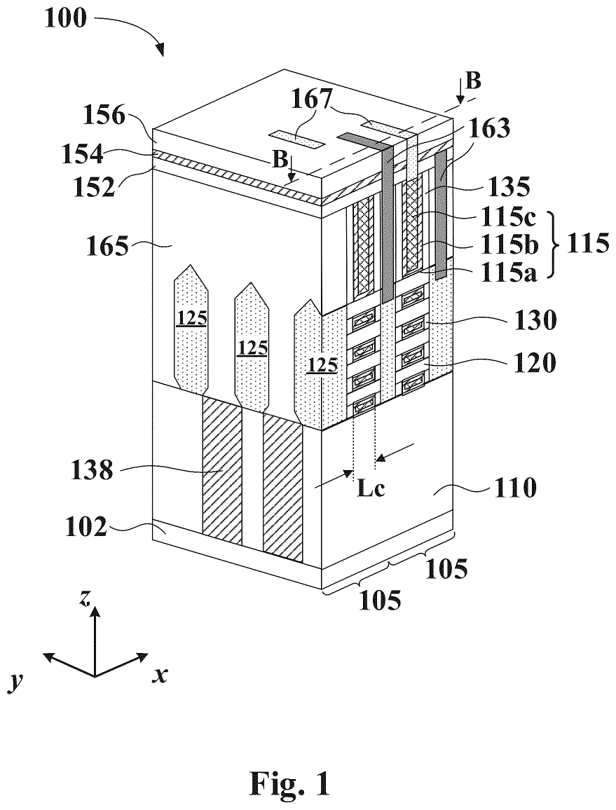

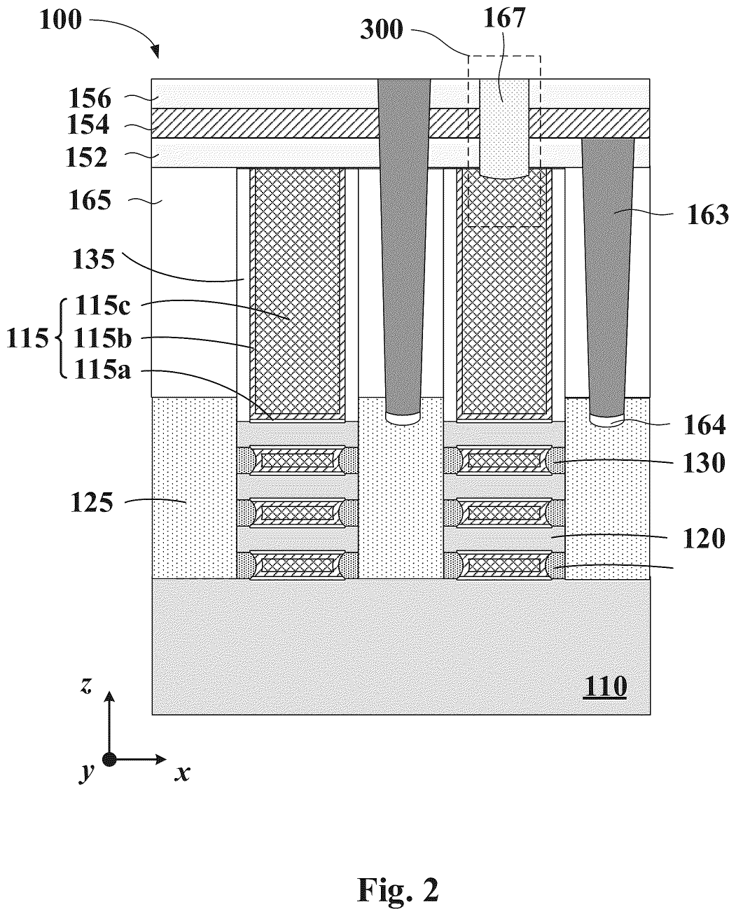

A semiconductor device 100 having multiple transistors 105 formed over a substrate 102 is described with reference to FIGS. 1 and 2, according to some embodiments. Semiconductor device 100 can be included in a microprocessor, memory cell, or other integrated circuit (IC). FIG. 1 illustrates an isometric view of semiconductor device 100. FIG. 2 illustrates cross-sectional (e.g., along the x-z plane) view of semiconductor device 100 along line B-B of FIG. 1.

Referring to FIG. 1, substrate 102 can be a semiconductor material, such as silicon. In some embodiments, substrate 102 can include a crystalline silicon substrate (e.g., wafer). In some embodiments, substrate 102 can include (i) an elementary semiconductor, such as silicon (Si) or germanium (Ge); (ii) a compound semiconductor including silicon carbide (SiC), gallium arsenide (GaAs), gallium phosphide (GaP), indium phosphide (InP), indium arsenide (InAs), and/or indium antimonide (InSb); (iii) an alloy semiconductor including silicon germanium carbide (SiGeC), silicon germanium (SiGe), gallium arsenic phosphide (GaAsP), gallium indium phosphide (InGaP), gallium indium arsenide (InGaAs), gallium indium arsenic phosphide (InGaAsP), aluminum indium arsenide (InAlAs), and/or aluminum gallium arsenide (AlGaAs); or (iv) a combination thereof. Further, substrate 102 can be doped depending on design requirements (e.g., p-type substrate or n-type substrate). In some embodiments, substrate 102 can be doped with p-type dopants (e.g., boron (B), indium (In), aluminum (Al), or gallium (Ga)) or n-type dopants (e.g., phosphorus (P), arsenic (As), or antimony (Sb)). In some embodiments, a crystal orientation of substrate 102 can be (100), (110), or (111).

Although FIGS. 1 and 2 show fin structure 110 accommodating two transistors 105, any number of transistors 105 can be disposed along fin structure 110. In some embodiments, transistors 105 can include multiple fin structures 110 extending along a first horizontal direction (e.g., in the x-direction) and gate structure 115 traversing through the multiple fin structures 110 along a second horizontal direction (e.g., in the y-direction). In some embodiments, a crystal orientation of fin structures 110 can be the same as the crystal orientation of substrate 102.

Referring to FIGS. 1 and 2, one or more nano-sheet (NS) layers 120 can be disposed over fin structure 110. Each NS layer 120 can be wrapped by gate structure 115 to function as transistor 105's channel. For example, a top surface, side surfaces, and a bottom surface of each NS layer 120 can be surrounded and in physical contact with gate structure 115. Fin structure 110 and NS layer 120 can be made of materials similar to (e.g., lattice mismatch within about 5%) substrate 102. In some embodiments, a crystal orientation of NS layer 120 can be the same as the crystal orientation of fin structures 110. In some embodiments, each of fin structure 110 and NS layer 120 can be made of Si or SiGe. Each of fin structure 110 and NS layer 120 can be un-doped, doped with p-type dopants, doped with n-type dopants, or doped with intrinsic dopants. In some embodiments, fin structure 110 and NS layers 120 can be doped together with p-type dopants or with n-type dopants. Although FIG. 1 shows that each transistor 105 includes four NS layers 120 and FIG. 2 shows that each transistor 105 includes three NS layers 120, any number of NS layers 120 can be included in each transistor 105. For example, each transistor 105 can include one, two, five, or six NS layers 120.

Referring to FIGS. 1 and 2, gate structures 115 can be a multilayered structure that wraps around each NS layer 120 to modulate transistor 105. Gate structures 115 can have a length Lc representing transistor 105's channel length. Length Lc can have any suitable horizontal (e.g., in the x-direction) dimension, such as from about 3 nm to about 200 nm. In some embodiments, a height of gate structures 115 along a vertical direction (e.g., in the z-direction) above fin structure 110 can be between about 12 nm and about 14 nm. In some embodiments, the height of gate structures 115 above fin structure 110 can be greater than about 14 nm. By way of example and not limitation, each gate structure 115 can include a dielectric stack formed by an interfacial dielectric layer 115a and a gate dielectric layer 115b. Further, each gate structure 115 includes a gate electrode 115c with capping layers, one or more work function metallic layers, and a metal fill not individually shown in FIG. 1 for simplicity. Gate dielectric layer 115b can include any suitable dielectric material with any suitable thickness that can provide channel modulation for transistor 105. In some embodiments, gate dielectric layer 115b can be made of silicon oxide or a high-k dielectric material (e.g., hafnium oxide or aluminum oxide). In some embodiments, gate dielectric layer 115b can have a thickness ranging from about 1 nm to about 5 nm. Based on the disclosure herein, other materials and thicknesses for gate dielectric layer 115b are within the scope and spirit of this disclosure. Gate electrode 115c can function as a gate terminal for transistor 105. Gate electrode 115c can include any suitable conductive material that provides a suitable work function to modulate transistor 105. In some embodiments, gate electrode 115c can be made of titanium nitride, tantalum nitride, tungsten nitride, titanium, aluminum, copper, tungsten, tantalum, copper, or nickel. Based on the disclosure herein, other materials for gate electrode 115c are within the scope and spirit of this disclosure.

Referring to FIGS. 1 and 2, S/D epitaxial structures 125 can be disposed over opposite sides (e.g., along the x-direction) of each NS layer 120 to function as transistor 105's source and drain terminals. S/D epitaxial structures 125 can be disposed on fin structures 110. In some embodiments, S/D epitaxial structures 125 can be disposed on fin structures 110, such that S/D epitaxial structures 125 and fin structures 110 are electrically isolated. S/D epitaxial structure 125 can be made of an epitaxially-grown semiconductor material similar to (e.g., lattice mismatch within about 5%) NS layer 120. In some embodiments, S/D epitaxial structures 125 can be made of Si, Ge, SiGe, InGaAs, or GaAs. S/D epitaxial structures 125 can be doped with p-type dopants, n-type dopants, or intrinsic dopants. In some embodiments, S/D epitaxial structures 125 can have a different doping type from NS layer 120. In some embodiments, the n-type dopants in S/D epitaxial structure 125 can include P, As, Sb, or a combination thereof. In some embodiments, a crystal orientation of S/D epitaxial structure 125 can be the same as the crystal orientation of NS layer 120.

Referring to FIGS. 1 and 2, semiconductor device 100 can include inner spacer structures 130 abutting (or in contact with) side surfaces of gate structures 115. Inner spacer structures 130 can separate gate structures 115 from S/D epitaxial structures 125. For example, inner spacer structures 130 can be formed at gate structures 115's opposite sides along transistors 105's channel direction (e.g., along the x-direction) to separate gate structures 115 from S/D epitaxial structures 125. In some embodiments, inner spacer structures 130 can be formed between two vertically (e.g., in the z-direction) adjacent NS layers 120. In some embodiments, inner spacer structures 130 can be formed between fin structures 110 and NS layers 120. In some embodiments, inner spacer structures 130 can include a silicon-based dielectric, such as silicon nitride (SiN), silicon oxy-carbon-nitride (SiOCN), silicon carbon-nitride (SiCN), or silicon oxy-nitride (SiON). In some embodiments, inner spacer structures 130 can include a low-k material, such as a porous material and a carbon-rich silicon oxide based dielectrics.

Referring to FIGS. 1 and 2, semiconductor device 100 can further include gate spacers 135 formed between gate structure 115 and S/D epitaxial structure 125, which can provide structural support during the formation of gate structures 115. In addition, gate spacers 135 can provide gate structures 115 with electrical isolation and protection during the formation of S/D contacts, which are not shown in FIG. 1. Gate spacers 135 can be made of any suitable dielectric material. In some embodiments, gate spacers 135 can be made of silicon oxide, silicon nitride, or a low-k material with a dielectric constant less than about 3.9. In some embodiments, gate spacers 135 can have any suitable thickness, such as from about 5 nm to about 15 nm. Based on the disclosure herein, other materials and thicknesses for gate spacers 135 are within the scope and spirit of this disclosure.

Referring to FIG. 1, semiconductor device 100 can further include shallow trench isolation (STI) regions 138 configured to provide electrical isolation between fin structures 110. STI regions 138 can also provide electrical isolation between transistor 105 and neighboring active and passive elements integrated with or deposited on substrate 102. STI regions 138 can include one or more layers of dielectric material, such as a nitride layer, an oxide layer disposed on the nitride layer, and an insulating layer disposed on the nitride layer. In some embodiments, the insulating layer can include silicon oxide, silicon nitride, silicon oxynitride, fluorine-doped silicate glass (FSG), a low-k dielectric material, and/or other suitable insulating materials. Based on the disclosure herein, other dielectric materials for STI regions 138 are within the scope and spirit of this disclosure.

Referring to FIGS. 1 and 2, semiconductor device 100 can further include interlayer dielectric (ILD) layers 165 to provide electrical isolation to structural elements it surrounds or covers, such as gate structures 115 and S/D epitaxial structures 125. In some embodiments, gate spacers 135 can be formed between gate structures 115 and ILD layers 165. ILD layers 165 can include any suitable dielectric material to provide electrical insulation, such as silicon oxide, silicon dioxide, silicon oxycarbide, silicon oxynitride, silicon oxy-carbon nitride, and silicon carbonitride. ILD layers 165 can have any suitable thickness, such as from about 50 nm to about 200 nm, to provide electrical insulation. Based on the disclosure herein, other insulating materials and thicknesses for ILD layers 165 are within the scope and spirit of this disclosure.

Referring to FIGS. 1 and 2, semiconductor device 100 can further include dielectric layers 152, 154, and 156 on transistors 105. In some embodiments, dielectric layers 152, 154, and 156 can include silicon oxide and/or silicon nitride. For example, dielectric layers 152 and 156 can be layers of silicon oxide, and dielectric layers 154 can be a layer of silicon nitride. In some embodiments, dielectric layers 152, 154, and 156 can be etch stop layers.

Referring to FIGS. 1 and 2, semiconductor device 100 can further include S/D contacts 163 in contact with S/D epitaxial structures 125. S/D contacts 163 can be disposed on S/D epitaxial structures 125 and surrounded by ILD layers 165. In some embodiments, S/D contacts 163 can be disposed through one or more of dielectric layers 152, 154, and 156. In some embodiments, silicide layers 164 can be disposed between S/D contacts 163 and S/D epitaxial structures 125. In some embodiments, a height of S/D contacts 163 can be between about 10 nm and about 50 nm. S/D contacts 163 can include any suitable conductive material that provides low contact resistance with S/D epitaxial structures 125. In some embodiments, S/D contacts 163 can be made of polysilicon, titanium nitride, tantalum nitride, tungsten nitride, titanium, aluminum, copper, tungsten, tantalum, nickel, or a combination thereof. Based on the disclosure herein, other materials for S/D contacts 163 are within the scope and spirit of this disclosure.

Referring to FIGS. 1 and 2, semiconductor device 100 can further include one or more gate contact vias 167 in contact with gate electrode 115c. Gate contact via 167 can be disposed on gate structures 115 and through one or more of dielectric layers 152, 154, and 156. In some embodiments, an interface between gate contact via 167 and gate electrode 115c can be substantially flat. In some embodiments, the interface between gate contact via 167 and gate electrode 115c can be curved. In some embodiments, a horizontal cross section of gate contact via 167 can have a rectangular shape or a cylindrical shape. In some embodiments, gate contact via 167 can have a tapered shape with a width of a top surface greater than a width of a bottom surface. In some embodiments, gate contact via 167 can have a uniform width from its top surface to its bottom surface. In some embodiments, the width of the top surface of gate contact via 167 can be between about 2 nm and about 40 nm. In some embodiments, the width of the bottom surface of gate contact via 167 can be between about 1 nm and about 40 nm. In some embodiments, a ratio of the width of the top surface of gate contact via 167 to the width of the bottom surface of gate contact via 167 can be between about 1 and about 3. In some embodiments, if the ratio is greater than about 3, the width of the bottom surface of gate contact via 167 can be too small, resulting in a higher contact resistance between gate contact via 167 and gate electrode 115c. In some embodiments, a height of gate contact via 167 can be between about 10 nm and about 50 nm. In some embodiments, an aspect ratio of gate contact via 167 can be between about 5:1 and about 20:1. In some embodiments, if the aspect ratio of gate contact via 167 is less than about 5:1, the width of gate contact via 167 may exceed a width of gate electrode 115c and interfere with surrounding contact structures, such as S/D contacts 163. In some embodiments, if the aspect ratio of gate contact via 167 is greater than about 20:1, gate contact via 167 may be too narrow, resulting in higher resistivity.

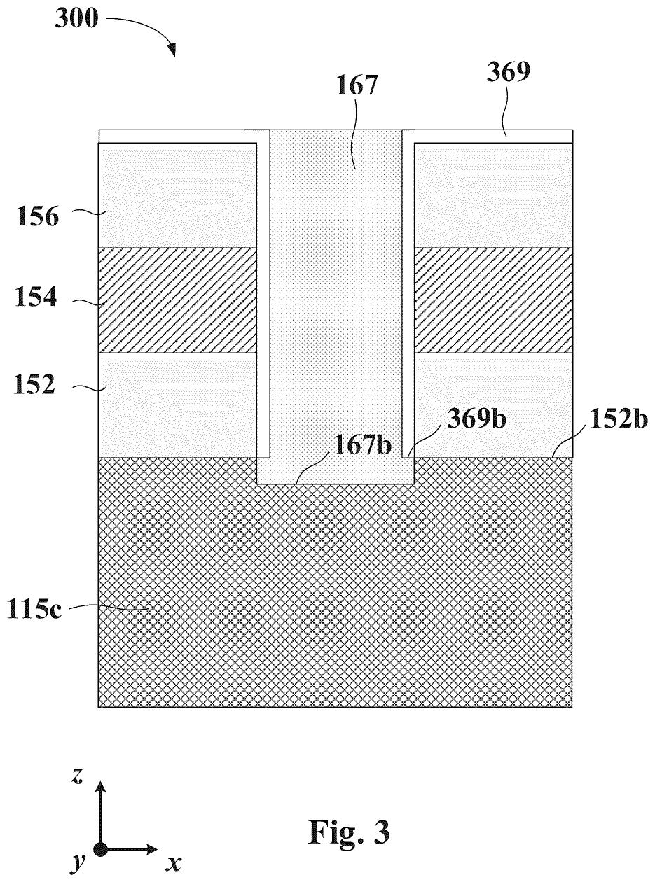

FIG. 3 illustrates a zoomed-in portion 300 in the cross-sectional view in FIG. 2 around the region of gate contact via 167. The discussion of elements in FIGS. 1 and 2 with the same annotations applies to FIG. 3, unless mentioned otherwise.

Referring to FIG. 3, in some embodiments, gate contact via 167 can be a conductive layer including a metallic material, of which a product of resistivity and electron mean free path is below about 400 μΩ·um². For example, the metallic material can include Ru. In some embodiments, the metallic material can include Ru, Ir, Co, or a combination thereof. In some embodiments, the metallic material can include Ru, Ir, Co, W, Cu, Mo, or a combination thereof. In some embodiments, an interface 167b between gate contact via 167 and gate electrode 115c can be oxygen-free. For example, an atomic percentage of oxygen at interface 167b can be less than about 3.5%. In some embodiments, if the atomic percentage of oxygen at interface 167b is greater than about 3.5%, the conductive performance of gate contact via 167 can be affected due to a high contact resistance between gate contact via 167 and gate electrode 115c.

In some embodiments, a self-assembling monolayer (SAM) 369 can be disposed between gate contact via 167 and dielectric layers 152, 154, and 156. SAM 369 is a passivation layer that inhibits the metallic material from being deposited on dielectric layers 152, 154, and 156. In some embodiments, SAM 369 can include an aminosilane functional group. For example, SAM 369 can include dimethylamino-trimethylsilane (TMSDMA), hexamethyldisilazane (HMDS), or a combination thereof. During a deposition process of gate contact via 167, as discussed below, the presence of SAM 369 can effectively prevent overhanging and early merging of metallic material on dielectric layers 152, 154, and 156, avoiding the formation of defects, voids, and/or discontinuities in gate contact via 167 and improving its conductive performance. In some embodiments, SAM 369 can cover an entire side surface of dielectric layers 152, 154, and 156, and a bottom end 369b of SAM 369 can be in contact with an end of an interface 152b between dielectric layers 152 and gate electrode 115c. In some embodiments, gate contact via 167 can protrude into gate electrode 115c, such that a portion of gate contact via 167 can be directly under bottom end 369b of SAM 369. In some embodiments, SAM 369 can cover a top surface of dielectric layer 156. In some embodiments, a top surface of gate contact via 167 and a top surface of SAM 369 can be coplanar.

Although FIGS. 1 and 2 illustrate embodiments in which transistors 105 are GAAFETs, it should be understandable that gate contact via 167 as described in FIG. 3 can be applied to other types of transistors, such as MOSFETs, FinFETs, complementary fin field effect transistors (CFETs), or vertical fin field effect transistors (VFETs).

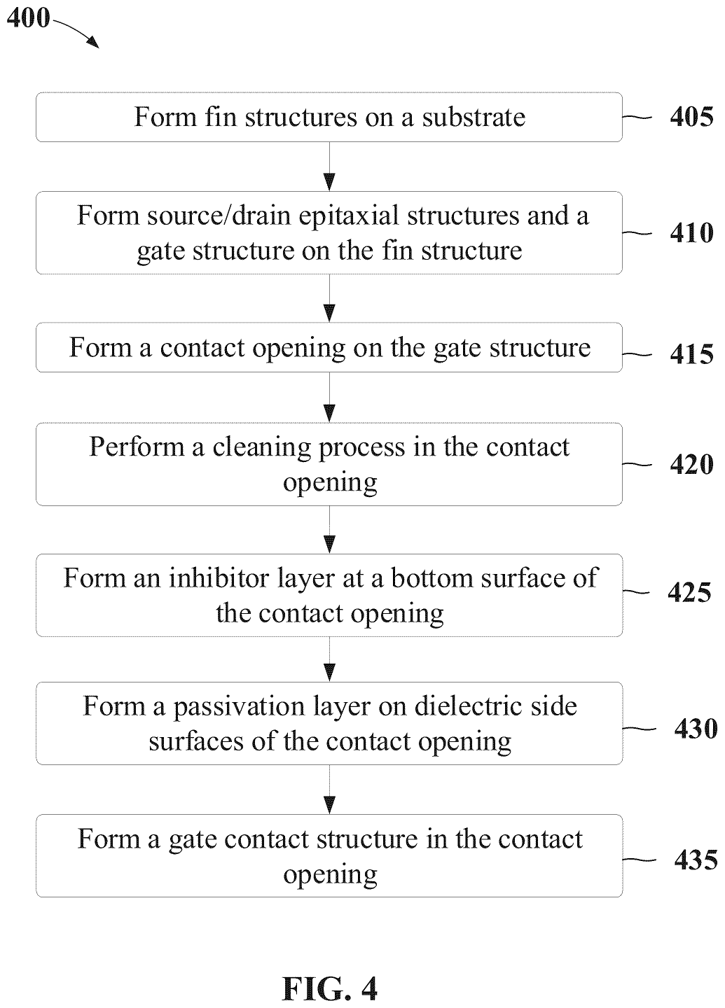

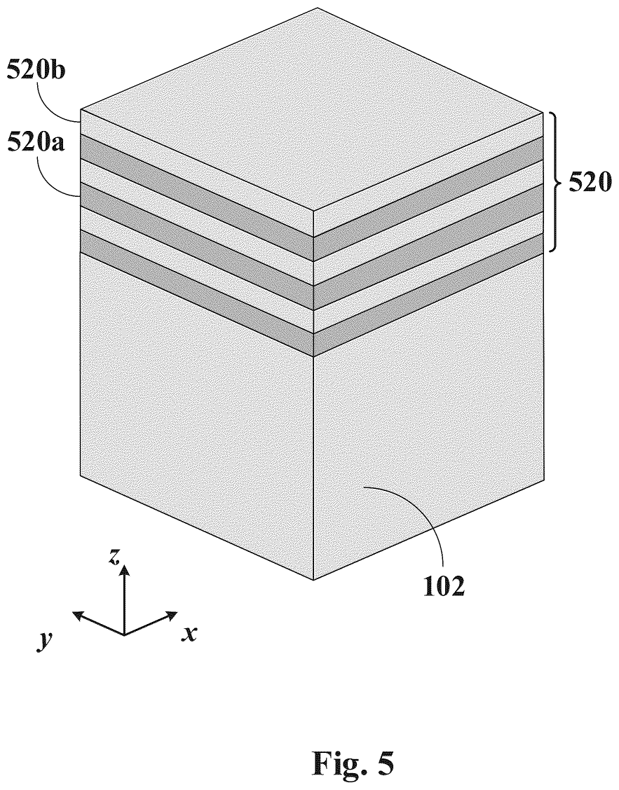

According to some embodiments, FIG. 4 illustrates a flowchart of a fabrication method 400 for the formation of transistors 105 shown in FIGS. 1-3. This disclosure is not limited to this operational description and additional operations may be performed. Other fabrication operations can be performed between the various operations of method 400 and are omitted merely for clarity. Moreover, not all operations may be needed to perform the disclosure provided herein. Additionally, some of the operations may be performed simultaneously, or in a different order than the ones shown in FIG. 4. In some embodiments, one or more other operations may be performed in addition to or in place of the presently described operations. For illustrative purposes, method 400 is described with reference to the structures shown in FIGS. 5-18 and 20-23. The discussion of elements in FIGS. 1-3 with the same annotations applies to FIGS. 5-18 and 20-23, unless mentioned otherwise.

Referring to FIG. 4, method 400 begins with operation 405 and the process of forming fin structures on a substrate (e.g., substrate 102). In some embodiments, forming the fin structures can include forming a stack of alternating first and second NS layers on the substrate, FIG. 5 is an isometric view of substrate 102 and the formation of a stack 520 of alternating first and second NS layers 520a and 520b. In some embodiments, first and second NS layers 520a and 520b are formed on an exposed top surface of substrate 102. In some embodiments, first NS layers 520a are sacrificial NS layers subject to subsequent removal and second NS layers 520b correspond to NS layers 120 shown in FIG. 1. In some embodiments, the material of first NS layers 520a in stack 520 is selected so that first NS layers 520a can be selectively removed via etching from stack 520 without removing second NS layers 520b. For example, first NS layers 520a can be SiGe NS layers and second NS layers 520b can be Si NS layers.

First and second NS layers 520a and 520b can be grown with any suitable method. For example, first and second NS layers 520a and 520b can be grown with a chemical vapor deposition (CVD) process with precursor gases, like silane (SiH₄), disilane (Si₂H₆), dichlorosilanc (SiH₂Cl₂), trichlorosilane (SiHCl₃), germane (GeH₄), digermane (Ge₂H₆), other suitable gases, or combinations thereof. In some embodiments, first NS layers 520a can include Ge with a concentration between about 20% and about 30%, while second NS layers 120 are substantially germanium-free—e.g., have a Ge concentration less than about 1%. In some embodiments, second NS layers 520b, which correspond to NS layers 120 in FIG. 1, form the channel region of transistor 105 and can be lightly doped or intrinsic (e.g., un-doped). If lightly doped, the doping level of second NS layers 520b is less than about 10¹³ atoms/cm³. First and second NS layers 520a and 520b can be sequentially deposited without a vacuum break (e.g., in-situ) to avoid the formation of any intervening layers. In some embodiments, first NS layers 520a can be doped to increase their etching selectivity compared to second NS layers 520b in a subsequent etching operation.

In some embodiments, a thickness of first NS layers 520a controls the spacing between every other second NS layer 520b in stack 520. The thickness of first and second NS layers 520a and 520b can range, for example, from about 3 nm to about 15 nm. Since first and second NS layers 520a and 520b are grown individually, the thickness of each NS layer can be adjusted independently based, for example, on the deposition time. In some embodiments, additional or fewer number of first and second NS layers 520a and 520b can be formed in stack 520. In some embodiments, a total number of NS layers can be 2n, where n is the number of first NS layers 520a or the number of second NS layers 520b in stack 520. In some embodiments, n can be 1, 2, 3, 4, 5, 6, or any integer number greater than 6.

Referring to FIG. 4, operation 405 can further include a process of patterning stack 520 to form the fin structures. In some embodiments, stack 520 is patterned to form the fin structures with a width along the y-direction and a length along the x-direction. The fin structures can be formed by patterning with any suitable method. For example, the fin structures may be patterned using one or more photolithography processes, including double-patterning or multi-patterning processes. Double-patterning or multi-patterning processes can combine photolithography and self-aligned processes, allowing patterns to be created that have, for example, pitches smaller than what is otherwise obtainable using a single, direct photolithography process. In some embodiments, a sacrificial layer is formed over stack 520 and patterned using a photolithography process. Spacers are formed alongside the patterned sacrificial layer using a self-aligned process. The sacrificial layer is then removed, and the remaining spacers may then be used as masking structures to pattern the fin structures.

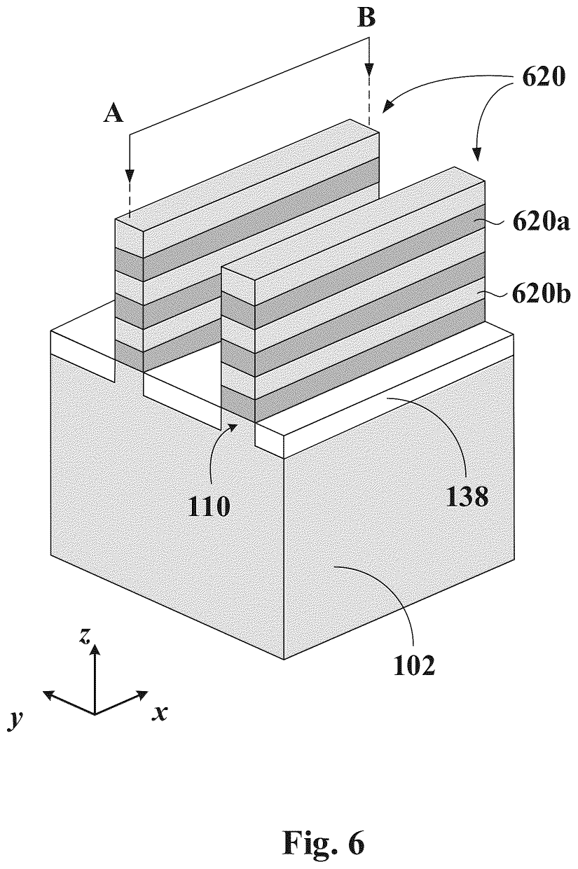

By way of example and not limitation, FIG. 6 is an isometric view of fin structures 620 formed from stack 520 with the aforementioned patterning process. In some embodiments, fin structures 620 can be formed by etching first and second NS layers 520a and 520b into first and second NS layers 620a and 620b. In some embodiments, the aforementioned patterning process does not terminate on the top surface of substrate 102 but continues to etch a top portion substrate 102 to form fin structures 110 from substrate 102 under fin structures 620. Since fin structures 620 and fin structures 110 are formed with the same patterning process, fin structures 620 and fin structures 110 are substantially aligned to each other. For example, sidewall surfaces of fin structures 620 in the x-z plane and y-z plane are substantially aligned to respective sidewall surfaces of fin structures 110 as shown in FIG. 6.

Additional fin structures, like fin structures 620, can be formed on substrate 102 in the same or different area of substrate 102. These additional fin structures are not shown in FIG. 6 for simplicity. By way of example and not limitation, each fin structure 620 has a width along the y-direction between about 15 nm and about 150 nm.

In some embodiments, NS layers 620a and 620b are referred to as “nano-sheets” when their width along the y-direction is substantially different from their height along z-direction—for example, when their width is larger/narrower than their height. In some embodiments, NS layers 620a and 620b can also be referred to as “nano-wires” when their width along the y-direction is substantially equal to their height along z-direction. In some embodiments, NS layers 620a and 620b are deposited as nano-sheets and subsequently patterned to form nano-wires with substantially equal height and width. By way of example and not limitation, NS layers 620a and 620b will be described in the context of nano-sheets (NS) layers. Based on the disclosure herein, nano-wires (NW) are within the spirit and the scope of this disclosure. Further, for example purposes and without limiting the scope of this disclosure, first and second NS layers 620a and 620b in method 400 will be described in the context of SiGe and Si NS layers, respectively.

In some embodiments, after the formation of fin structures 620, STI regions 138 can be formed on etched or recessed portions of substrate 102 to cover sidewall surfaces of fin structures 110. In some embodiments, STI regions 138 can electrically isolate fin structures 110 and include one or more silicon oxide based dielectrics. By way of example and not limitation, STI regions 138 can be formed as follows. An isolation structure material (e.g., a silicon oxide based dielectric) is blanket deposited over fin structures 620 and substrate 102. The as-deposited isolation structure material is planarized (e.g., with a chemical mechanical polishing (CMP) process) so that the top surface of the isolation structure material is substantially coplanar with the top surface of fin structures 620. The planarized isolation structure material is subsequently etched back so that the resulting STI regions 138 has a height substantially similar to fin structures 110, as shown in FIG. 6. In some embodiments, fin structures 620 protrudes from STI regions 138 so that STI regions 138 does not cover sidewall portions of fin structures 620 as shown in FIG. 6.

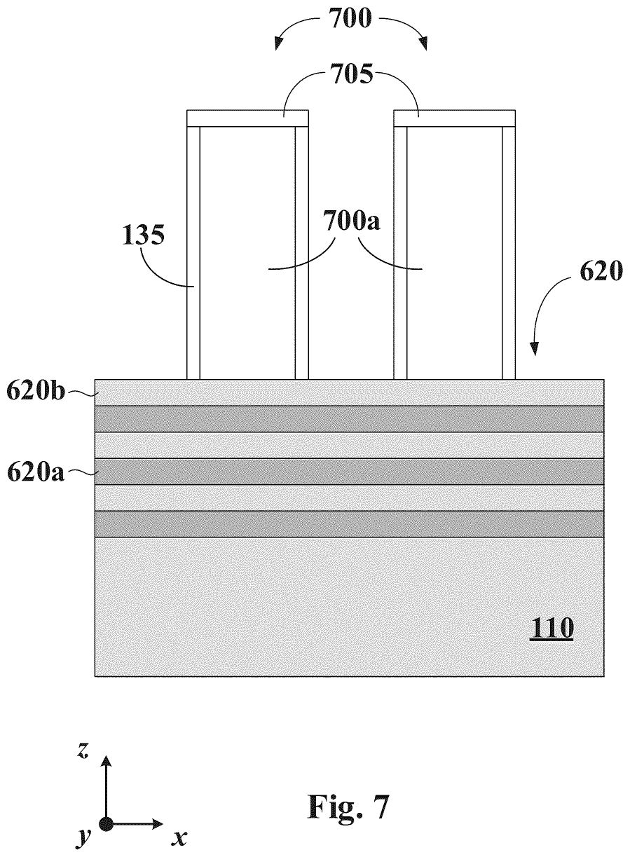

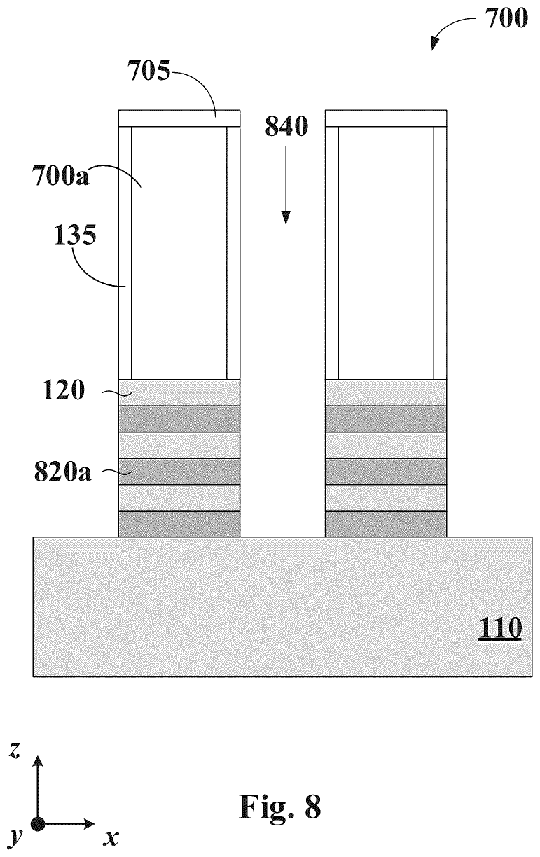

Method 400 continues with operation 410 and the process of forming S/D epitaxial structures and a gate structure on the fin structure. Operation 410 can start with removing portions of the fin structures to form openings in the fin structures, including (i) forming sacrificial gate structures 700, as described with reference to FIG. 7 and (ii) removing the portions of fin structure 620 exposed by sacrificial gate structures 700, as described with reference to FIG. 8.

In some embodiments, sacrificial gate structures 700 are formed with their length along the y-direction—e.g., perpendicular to fin structures 620 shown in the isometric view of FIG. 6—and their width along the x-direction. By way of example and not limitation, FIG. 7 is a cross-sectional view of FIG. 6 along cut-line AB. FIG. 7 shows sacrificial gate structures 700 formed on portions of fin structures 620. Because FIG. 7 is a cross-sectional view, as opposed to an isometric view, portions of sacrificial gate structures 700 covering sidewall portions of fin structures 620 are not shown. Further, in the cross-sectional view of FIG. 7, only one of fin structures 620 from FIG. 6 is shown. In some embodiments, portions of sacrificial gate structures 700 are formed between fin structures 620 and on STI regions 138 shown in FIG. 6.

In some embodiments, sacrificial gate structures 700 can cover top and sidewall portions of fin structures 620. Sacrificial gate structures 700 are subsequently replaced with gate structures 115 shown in FIG. 1 during a subsequent gate replacement process. Sacrificial gate structures 700 can include a sacrificial gate electrode 700a formed on a sacrificial gate dielectric not shown in FIG. 7 for simplicity. Sacrificial gate structures 700 can also include capping layers 705 formed on top surfaces of sacrificial gate structures 700. In some embodiments, capping layers 705 can protect sacrificial gate electrode 700a from subsequent etching operations. At this fabrication stage, gate spacers 135 can be formed on side surfaces of sacrificial gate structures 700. As discussed above, gate spacers 135 are not removed during the gate replacement process; instead, gate spacers 135 facilitate the formation of gate structures 115 as shown in FIG. 1.

By way of example and not limitation, sacrificial gate structures 700 can be formed by depositing and patterning sacrificial gate electrode 700a over fin structures 620. In some embodiments, sacrificial gate structures 700 are formed over multiple fin structures 620. As shown in FIG. 7, portions of fin structures 620 are not covered by sacrificial gate structures 700. This is because the width of sacrificial gate structures 700 is narrower than the length of fin structures 620 along the x-direction. In some embodiments, sacrificial gate structures 700 are used as masking structures in subsequent etching operations to define the channel region of transistors 105 shown in FIG. 1. For this reason, the lateral dimensions (e.g., the width and length) of sacrificial gate structures 700 and gate structures 115 arc substantially similar.

Referring to FIG. 8, portions of fin structures 620 not covered by sacrificial gate structures 700 can be removed. In some embodiments, the removal process involves a dry etching process, a wet etching process, or combinations thereof. The removal process is selective towards first NS layers 620a and second NS layers 620b, shaping them into first NS layers 820a and NS layers 120, respectively. The removal process can further remove portions of fin structure 110. In some embodiments, the dry etching process includes etchants having an oxygen-containing gas, a fluorine-containing gas (e.g., carbon tetrafluoride (CF₄), sulfur hexafluoride (SF₆), difluoromethane (CH₂F₂), trifluoromethane (CHF₃), and/or hexafluoroethane (C₂F₆)); a chlorine-containing gas (e.g., chlorine (Cl₂), chloroform (CHCl₃), carbon tetrachloride (CCl₄), and/or boron trichloride (BCl₃)); a bromine-containing gas (e.g., hydrogen bromide (HBr) and/or bromoform (CHBr₃)); an iodine-containing gas; other suitable etching gases and/or plasmas; or combinations thereof. The wet etching chemistry can include diluted hydrofluoric acid (DHF), potassium hydroxide (KOH) solution, ammonia; a solution containing hydrofluoric acid (HF), nitric acid (HNO₃), acetic acid (CH₃COOH); or combinations thereof.

In some embodiments, the etchants of the aforementioned etching process do not substantially etch sacrificial gate structures 700—which is protected by capping layers 705 and gate spacers 135—and STI regions 138 shown in FIG. 6. This is because capping layers 705, gate spacers 135, and STI regions 138 include materials with a low etching selectivity, such as a silicon nitride based material (e.g., silicon nitride, silicon carbon nitride, and silicon carbon oxy-nitride) or silicon oxide based materials. In some embodiments, STI regions 138 shown in FIG. 6 are used as an etch stop layer for the etching process described above.

After removing the portions of fin structures 620 not covered by sacrificial gate structures 700, openings 840 are formed in each fin structure 620 as shown in FIG. 8. Openings 840 divide each fin structure 620 into separate portions, with each portion covered by a sacrificial gate structure 700.

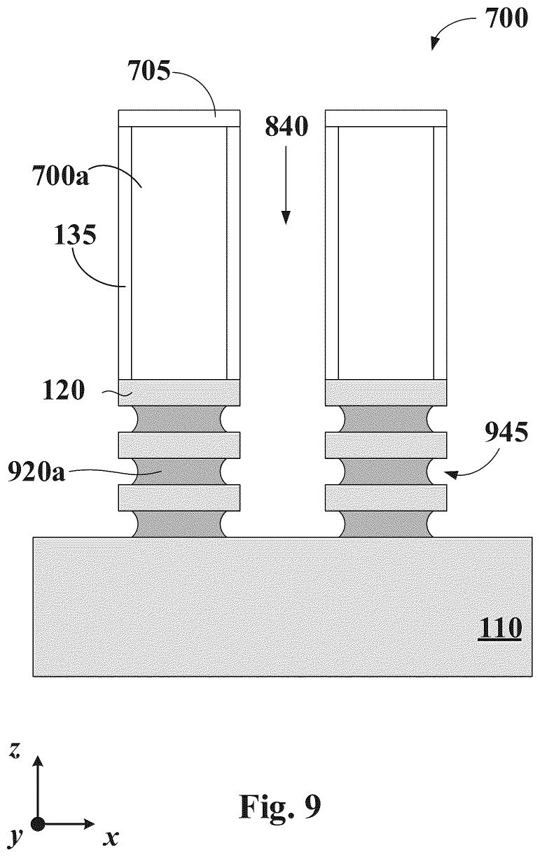

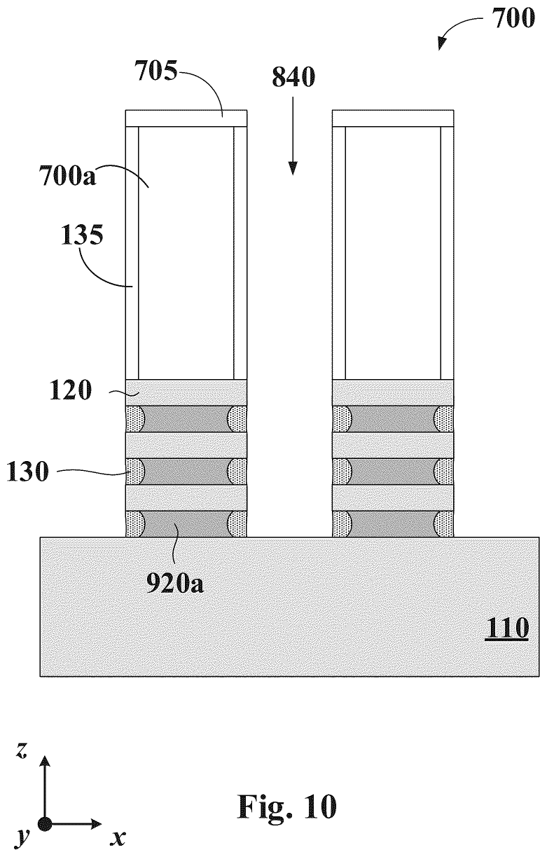

Referring to FIG. 4, operation 410 can continue with a process of forming inner spacers after forming openings 840. The process of forming inner spacers can include (i) selectively etching edge portions of first NS layers 820a to form recess structures 945, as described with reference to FIG. 9 and (ii) forming inner spacer structures 130 in recess structures 945, as described with reference to FIG. 10. According to some embodiments, FIG. 9 shows the structure of FIG. 8 after exposed edges of first NS layers 820a are laterally etched (e.g., recessed) along the x-direction and turned into first NS layers 920a. According to some embodiments, exposed edges of first NS layers 820a are recessed (e.g., partially etched) by an amount that ranges from about 3 nm to about 10 nm along the x-direction as shown in FIG. 9 to form recesses structures 945.

In some embodiments, the selective etching of first NS layers 820a can be achieved with a dry etching process selective towards SiGe. For example, halogen-based chemistries exhibit a high etching selectivity towards Ge and a low etching selectivity towards Si. Therefore, halogen gases etch Ge-containing layers, such as first NS layers 820a, at a higher etching rate than substantially Ge-free layers like NS layers 120. In some embodiments, the halogen-based chemistries include fluorine-based and/or chlorine-based gasses. Alternatively, a wet etching chemistry with high selectivity towards SiGe can be used. By way of example and not limitation, a wet etching chemistry may include a mixture of sulfuric acid (H₂SO₄) and hydrogen peroxide (H₂O₂) (SPM), or a mixture of ammonia hydroxide with H₂O₂ and water (APM). The aforementioned etching processes are timed so that the desired amount of SiGe is removed.

In some embodiments, first NS layers 820a with a higher Ge atomic concentration have a higher etching rate than NS layers 120 with a lower or zero Ge atomic concentration. Therefore, the etching rate of the aforementioned etching processes can be adjusted by modulating the Ge atomic concentration (e.g., the Ge content) in first NS layers 820a. As discussed above, the Ge content in first NS layers 820a can range between about 20% and about 30%. A SiGe nano-sheet layer with about 20% Ge can be etched slower than a SiGe nano-sheet layer with about 30% Ge. Consequently, the Ge concentration can be adjusted accordingly to achieve the desired etching rate and selectivity between first NS layers 820a and NS layers 120.

Referring to FIGS. 9 and 10, once recessed structures 945 are formed, a dielectric layer can be blanket deposited over the entire structure of FIG. 9, and the portion of the dielectric layer outside recess structures 945 can be removed, leaving inner spacer structures 130 behind filling recessed structures 945, as described with reference to FIG. 10.

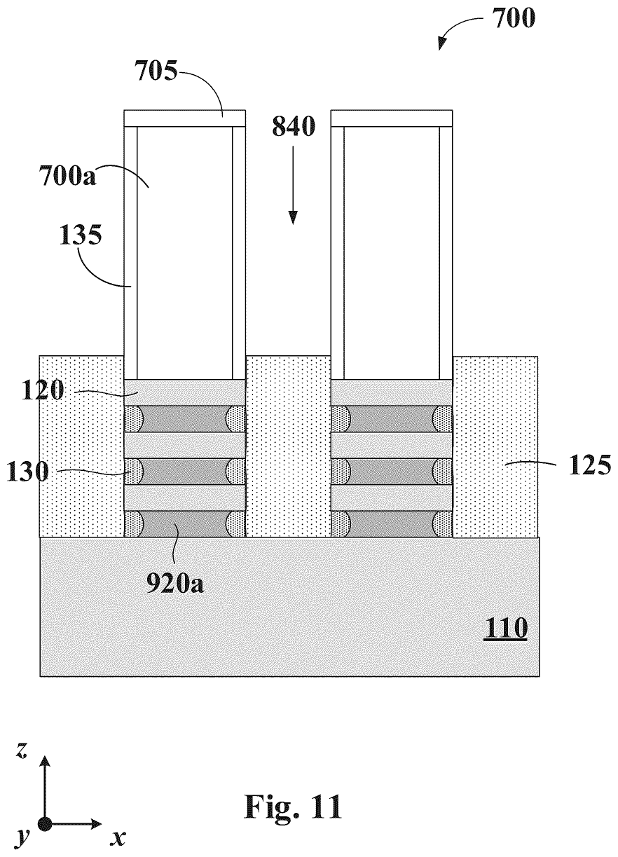

Referring to FIGS. 4, after forming inner spacer structures 130, operation 410 can continue with a process of forming S/D epitaxial structures in the openings 840. For example, as described with reference to FIG. 11, S/D epitaxial structures 125 can be formed by epitaxially growing a semiconductor material in openings 840.

In some embodiments, as described with reference to FIG. 11, S/D epitaxial structures 125 can be epitaxially grown with a CVD process similar to the one used in operation 405 to form first and second NS layers 520a and 520b, as described with reference to FIG. 5. In some embodiments, S/D epitaxial structures 125 can be epitaxially grown on side surfaces of second NS layers 120 in a horizontal direction (e.g., along the x-axis). In some embodiments, S/D epitaxial structures 125 can be epitaxially grown on top surfaces of fin structure 110 in a vertical direction (e.g., along the z-axis). In some embodiments, S/D epitaxial structures 125 can be grown using a plasma-enhanced CVD (PECVD) process. In some embodiments, precursor gases (e.g., SiH₄, SiH₂Cl₂, SiHCl₃, or a combination thereof) can be used to grow a semiconductor material (e.g., Si) having a crystalline structure the same as or similar to the crystalline structure of NS layers 120. In some embodiments, etching gases (e.g., hydrogen chloride (HCl)) can be used to selectively remove the semiconductor material with an amorphous structure formed on dielectric surfaces (e.g., side surfaces of inner spacer structures 130 and gate spacers 135). Removing the semiconductor material with the amorphous structure can ensure that the crystal structure of S/D epitaxial structures 125 is crystalline. In some embodiments, dopant precursor gases, such as phosphanes (PH₃), arsanes (AsH₃), stibane (SbH₃), or a combination thereof can be used in the CVD process or the PECVD process to dope S/D epitaxial structures 125.

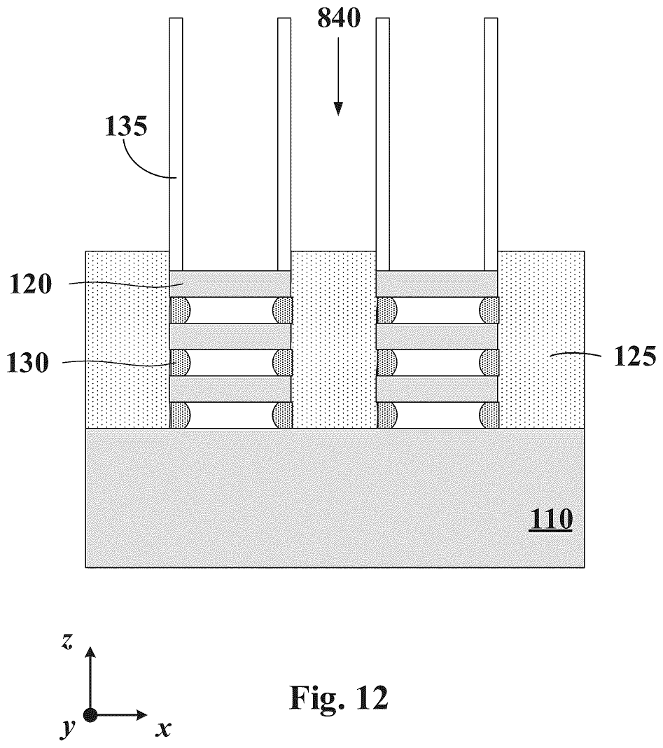

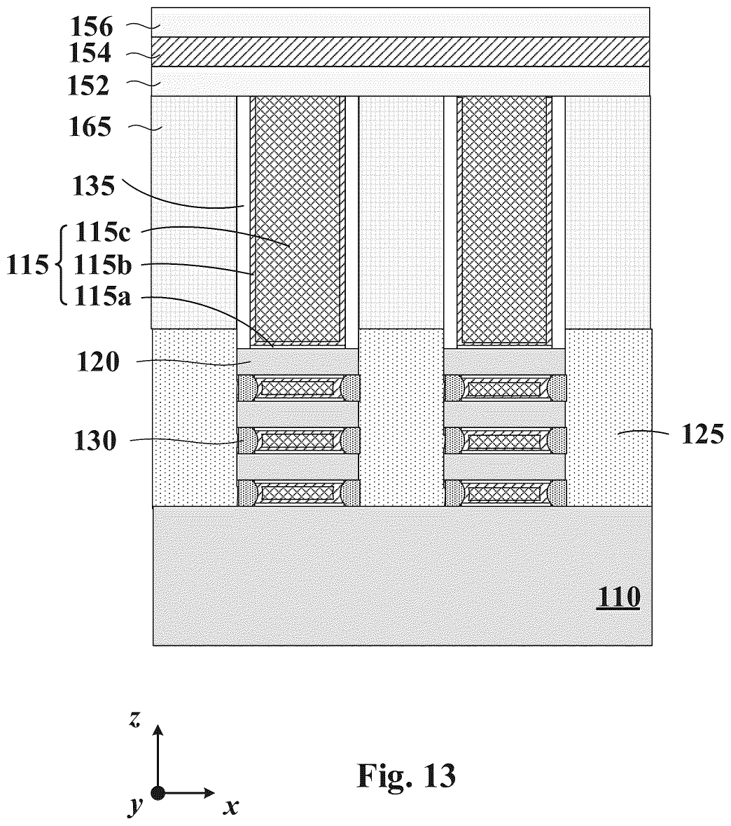

Referring to FIG. 4, operation 410 can continue with a process of forming a gate structure. The process of forming metal gate structures can include (i) removing sacrificial gate structures 700 and first NS layers 920a, as described with reference to FIG. 12, and (ii) forming metal gate structures 115 to surround second NS layers 120, as described with reference to FIG. 13.

In some embodiments, removing sacrificial gate structures 700 can include removing capping layer 705 to expose sacrificial gate electrode 700a, and subsequently, removing sacrificial gate electrode 700a to expose fin structures 620 between S/D epitaxial structures 125. In some embodiments, removing first NS layers 920a can include selectively etching first NS layers 920a without removing NS layers 120 as described with reference to FIG. 12.

In some embodiments, forming metal gate structures 115 can include (i) forming interfacial dielectric layer 115a on exposed surfaces of second NS layers 120, (ii) forming gate dielectric layer 115b on interfacial dielectric layer 115a, and (iii) forming gate electrode 115c on gate dielectric layer 115b, as described with reference to FIG. 13. As discussed above, metal gate structures 115 are electrically isolated from S/D epitaxial structures 125 by inner spacer structures 130 and gate spacers 135. In some embodiments, after forming metal gate structures 115, ILD layer 165 can be formed to fill the space above S/D epitaxial structures 125. In some embodiments, one or more of dielectric layers 152, 154, and 156 can be formed over metal gate structures 115 and ILD layer 165 by sequential deposition of dielectric layers such as silicon oxide and silicon nitride.

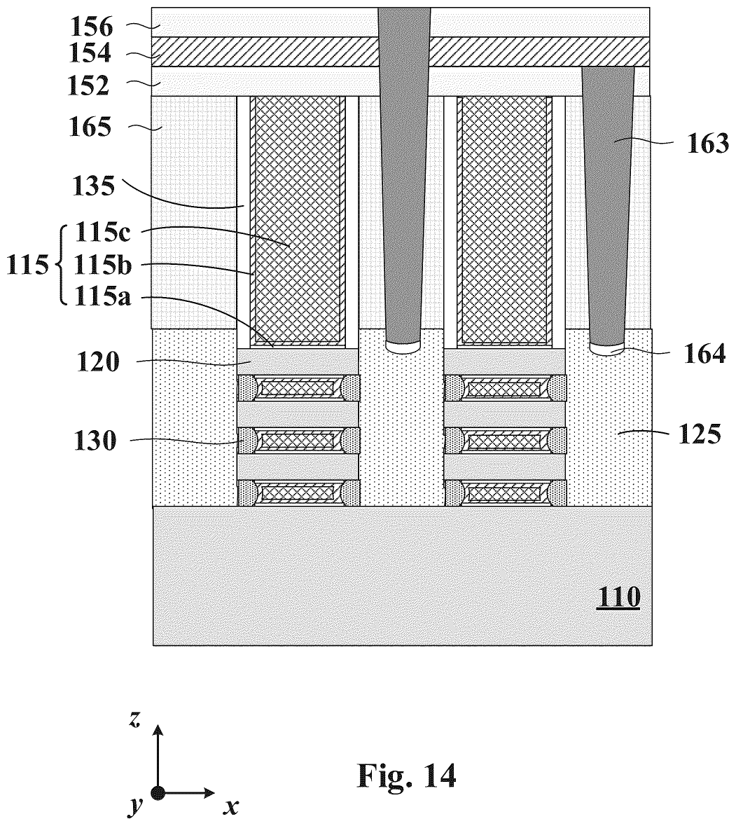

Referring to FIG. 4, operation 410 can continue with a process of forming S/D contacts 163, as described with reference to FIG. 14. In some embodiments, forming S/D contacts 163 can include (i) forming openings through one or more of dielectric layers 152, 154, and 156 and though ILD layer 165 to expose S/D epitaxial structures 125, (ii) forming a silicide layer 164 on S/D epitaxial structures 125, and (iii) depositing a metallic material (e.g., W, Cu, and/or Mo) in the openings.

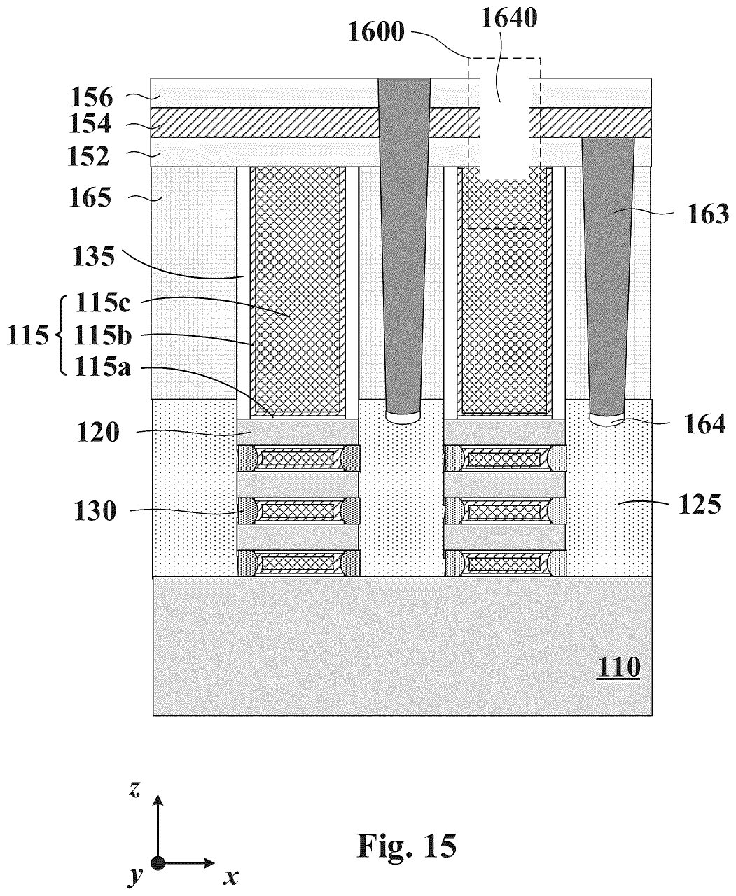

Referring to FIG. 4, method 400 continues with operation 415, in which a contact opening is formed on the gate structure. For examples, as described with reference to FIG. 15, a contact opening 1640 is formed through one or more of dielectric layers 152, 154, and 156 to expose gate electrode 115c. In some embodiments, contact opening 1640 can be formed to protrude into gate electrode 115c. In some embodiments, the formation of contact opening 1640 can include a dry etching process with one or more etchants and can include sequential operations of (i) etching portions of dielectric layers 152, 154, or 156 and (ii) etching portions of gate electrode 115c, as described with reference to FIG. 15. Contact opening 1640 can expose a top surface of gate electrode 115c and side surfaces of dielectric layers 152, 154, or 156. In some embodiments, contact opening 1640 can have a vertical cross-sectional profile with vertical or slanted side surfaces. In some embodiments, contact opening 1640 can have a horizontal cross-sectional profile with a rectangular shape or a circular shape.

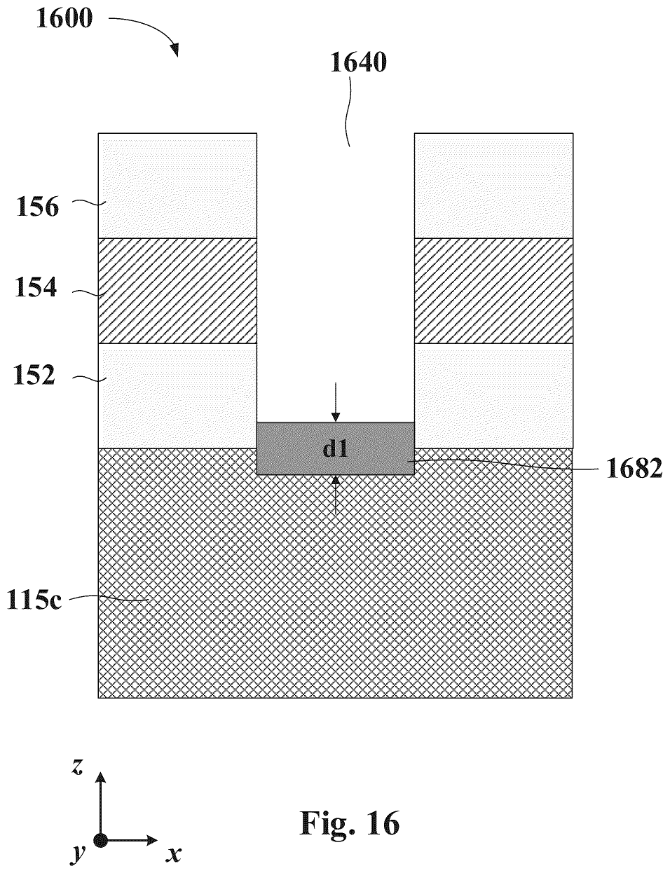

In some embodiments, during formation of contact opening 1640, the top surface of gate electrode 115c can be oxidized due to the reaction between the etchants and the metallic material (e.g., TiN) of gate electrode 115c. FIG. 16 illustrates a zoomed-in region 1600 around contact opening 1640 in FIG. 15. As shown in FIG. 16, an oxide layer 1682 can be formed on gate electrode 115c. In some embodiments, oxide layer 1682 can be formed due to a reaction between oxygen and the metallic material at the top surface of gate electrode 115c. In some embodiments, a thickness d1 of oxide layer 1682 can be between about 0.5 nm and about 5 nm. In some embodiments, oxide layer 1682 can include titanium oxynitride (TiOₓN_{y}).

As the presence of oxide layer 1682 can increase the contact resistance between gate electrode 115c and a subsequently formed gate contact via, oxide layer 1682 can be removed in a subsequent operation 420 prior to the formation of the gate contact via.

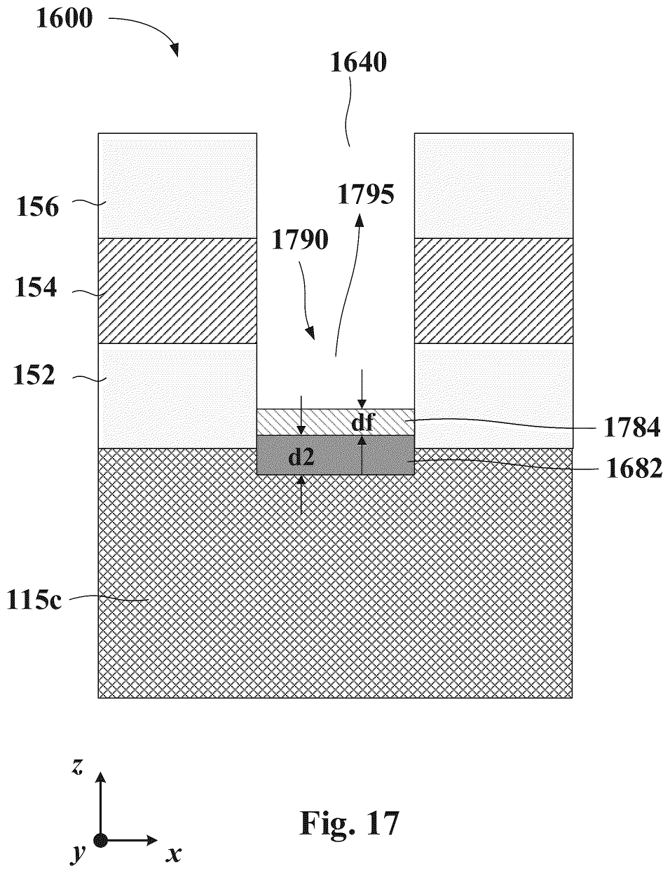

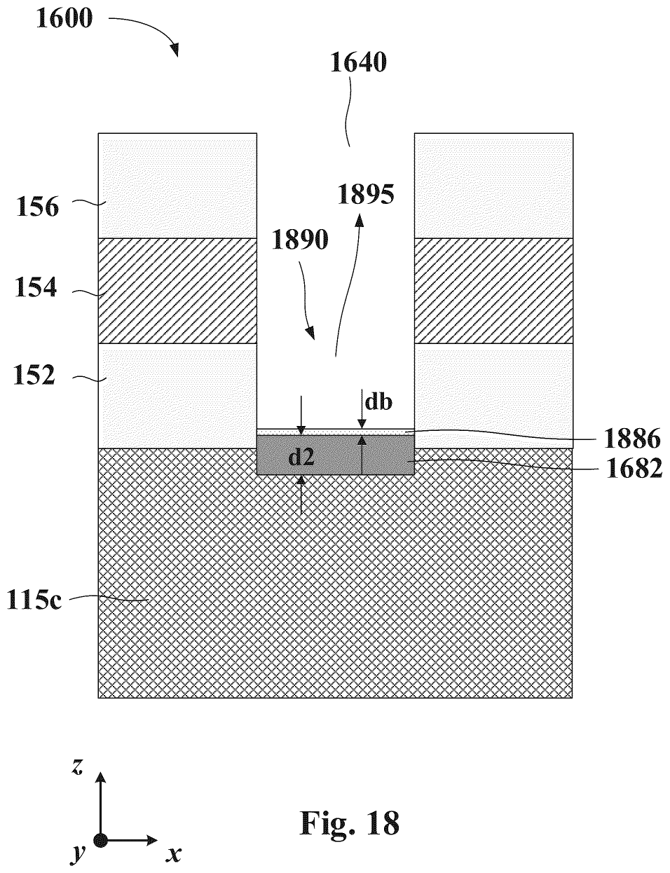

Referring to FIG. 4, method 400 continues with operation 420, in which a cleaning process is performed in the contact opening. For example, as described with reference to FIGS. 17-20, a cleaning process is performed in contact opening 1640 to remove oxide layer 1682. In some embodiments, the cleaning process can include using a non-plasma-based cleaning process, such as an atomic layer etch (ALE) process that include one or more cycles. In some embodiments, the cleaning process can include removing about one atomic layer (e.g., about 0.1 nm) of oxide layer 1682 in each cycle of an ALE process. In some embodiments, each cycle of the ALE process can include sequential operations of (i) exposing oxide layer 1682 to a fluorine-based etching gas 1790 (e.g., tungsten hexafluoride (WF₆) or hydrogen fluoride (HF)), which react with about one atomic layer of oxide layer 1682 to form a first byproduct layer 1784 with a thickness df on oxide layer 1682 of reduced thickness d2 and a first byproduct gas 1795, as shown in FIG. 17, and (ii) exposing byproduct layer 1784 to a reactant gas 1890 (e.g., boron trichloride (BCl₃)) to remove first byproduct layer 1784 and form a second byproduct layer 1886 on oxide layer 1682 and a second byproduct gas 1895, as shown in FIG. 18. In a subsequent cycle of the ALE process, second byproduct layer 1886 can further be removed when exposed to fluorine-based etching gas 1790, which further reduces the thickness of oxide layer 1682 similar to step (i) as described above with reference to FIG. 17.

In some embodiments, first byproduct layer 1784 can include tungsten oxygen nitrogen fluoride (WONF) and/or titanium oxygen nitrogen fluoride (TIONF). In some embodiments, second byproduct layer 1886 can include boron oxygen nitrogen (BOₓN_{y}). In some embodiments, first byproduct gas 1795 can include boron trifluoride (BF₃). In some embodiments, second byproduct gas 1895 can include tungsten oxytetrachloride (WOCl₄), titanium tetrachloride (TiCl₄), boron trifluoride (BF₃), and nitrogen chloride (NClₓ).

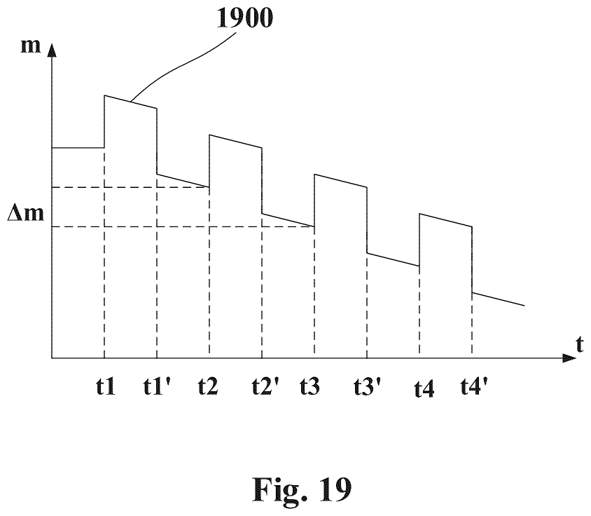

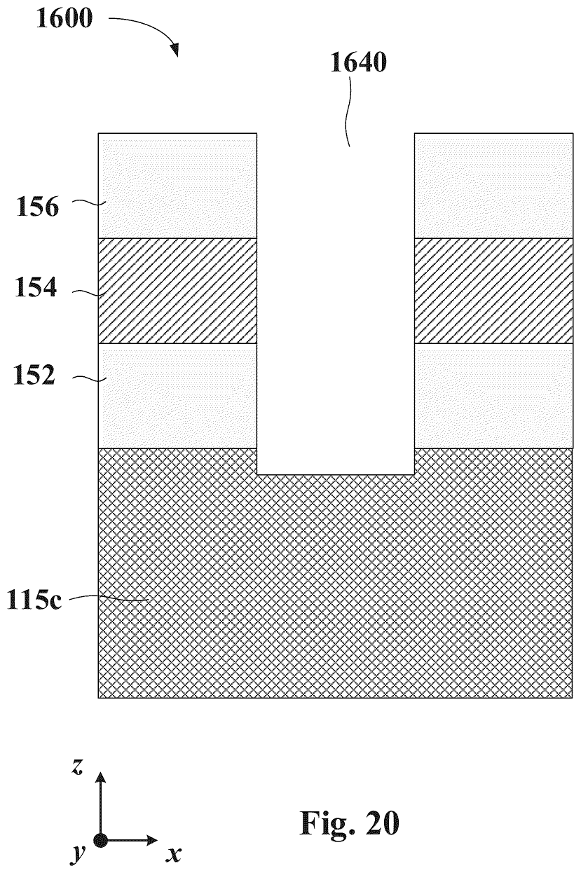

The cleaning process can include any number of cycles of the ALE process and the number of cycles can depend on the thickness of oxide layer 1682. For example, FIG. 19 shows a diagram about a mass loading 1900 of oxide layer 1682 during the cleaning process. At the beginning of each cycle (at times t1, t2, t3, and t4), as oxide layer 1682 is exposed to fluorine-based etching gas 1790, mass loading 1900 increases, corresponding to the formation of first byproduct layers 1784. Within each cycle when reactant gas 1890 is introduced into contact opening 1640 (at times t1′, t2′, t3′, and t4′), mass loading 1900 decreases, corresponding to the removal or reduction of first byproduct layers 1784 into second byproduct layer 1886. Between adjacent cycles, a mass difference Δm corresponds to a reduced thickness of oxide layer 1682 by d2-d1, which can be between about 0.2 nm and about 1 nm. In some embodiments, mass loading 1900 can be monitored in real-time, and the cleaning process can continue until oxide layer 1682 is totally removed as shown in FIG. 20, corresponding to negligible mass difference between adjacent cycles of the ALE process in mass loading 1900.

In some embodiments, the flow rate of fluorine-based etching gas 1790 and reactant gas 1890 can be between about 10 sccm and about 100 sccm. In some embodiments, the ALE process can be performed at a temperature between about 150° C. and about 300° C. and at a pressure between about 1 torr and about 10 torr.

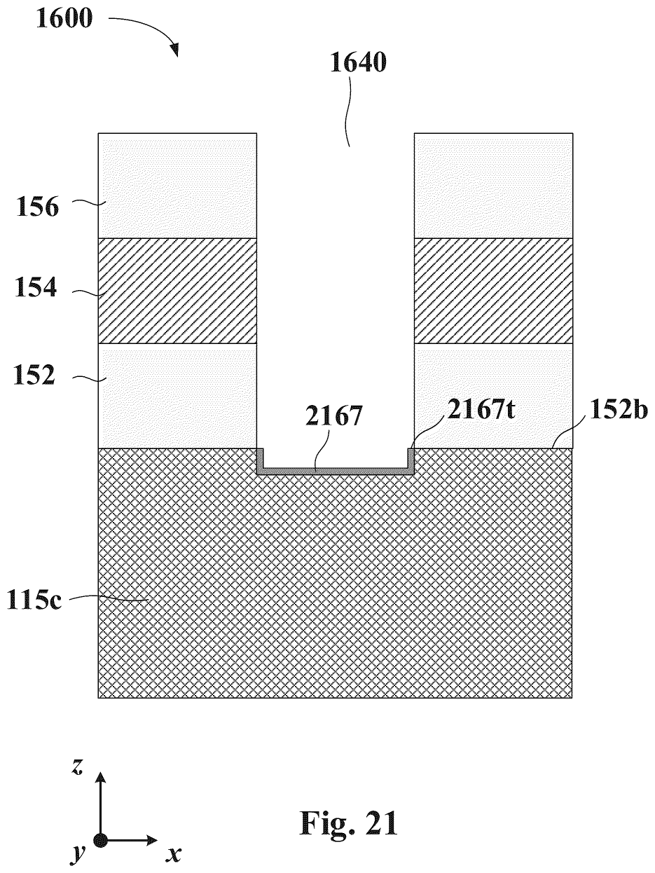

Referring to FIG. 4, method 400 continues with operation 425, in which an inhibitor layer is formed on a bottom surface of the contact opening. For example, as described with reference to FIG. 21, an inhibitor layer 2167 is deposited at the bottom surface of contact opening 1640, which is also the exposed top surface of gate electrode 115c. In some embodiments, forming inhibitor layer 2167 can include depositing a layer of single molecule inhibitor with molecules including nitrogen and aromatic rings, such as pyridine, aniline, pyrrole, or a combination thereof. In some embodiments, inhibitor layer 2167 can be formed at a temperature between about 150° C. and about 300° C. and at a pressure between about 1 torr and about 10 torr. In some embodiments, due to the chemical structure of the molecules and proper deposition conditions, inhibitor layer 2167 can be selectively formed only on conductive surfaces (e.g., exposed top surface of gate electrode 115c) but not on non-conductive surfaces (e.g., dielectric side surfaces or top surfaces of dielectric layers 152, 154, or 156). In some embodiments, inhibitor layer 2167 can include portions covering side surfaces of gate electrode 115c in contact opening 1640, as shown in FIG. 21. In some embodiments, a top end 2167t of inhibitor layer 2167 can be in contact with an end of interface 152b between gate electrode 115c and dielectric layer 152.

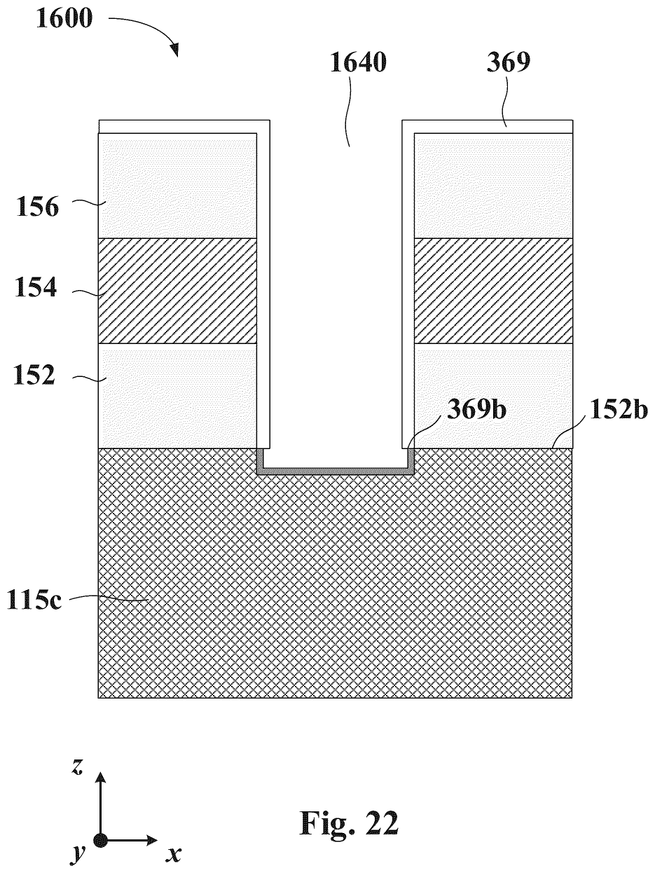

Referring to FIG. 4, method 400 continues with operation 430, in which a passivation layer is formed on side surfaces of the contact opening. For example, as described with reference to FIG. 22, SAM 369 as a passivation layer can be formed on the side surfaces of contact opening 1640. In some embodiments, SAM 369 can be formed to cover all dielectric surfaces exposed in contact opening 1640, such that the subsequent metal deposition in contact opening 1640 does not form overhang or early merging structures on the dielectric surfaces of contact opening 1640. In some embodiments, SAM 369 can also be formed on top surfaces of dielectric layer 156. In some embodiments, forming SAM 369 can include depositing a material with aminosilane functional groups, such as TMSDMA, HMDS, or a combination thereof. In some embodiments, since inhibitor layer 2167 repels aminosilane functional groups, the presence of inhibitor layer 2167 can prevent the formation of SAM 369 on a exposed surfaces of inhibitor layer 2167.

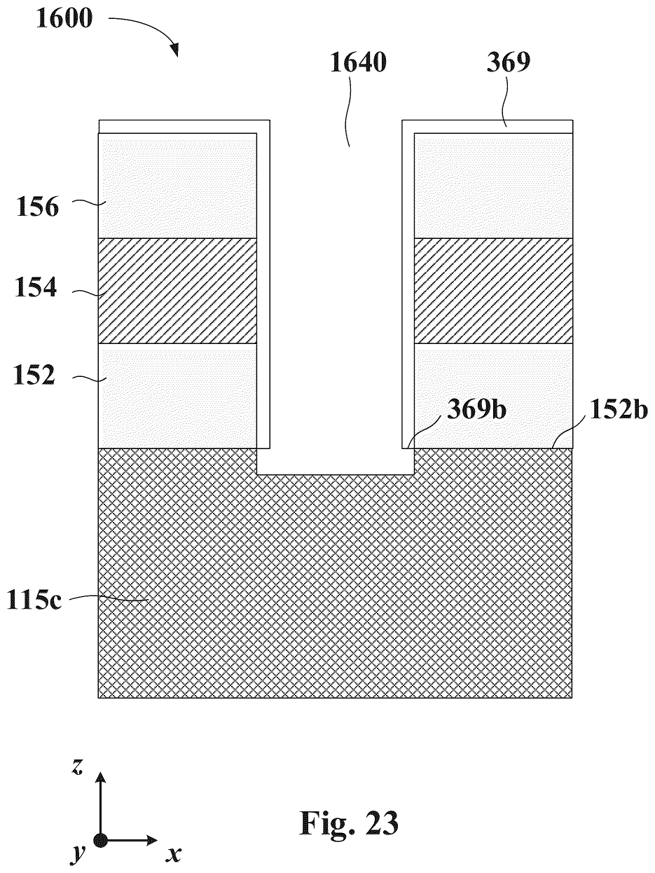

Referring to FIG. 4, method 400 continues with operation 435, in which a gate contact structure is formed in the contact opening. In some embodiments, forming the gate contact structure can include (i) annealing the structure as shown in FIG. 22 in a hydrogen (H₂) environment and at a temperature between about 350° C. and 450° C. to release inhibitor layer 2167 and expose the top surface of gate electrode 115c in contact opening 1640, as shown in FIG. 23, and (ii) forming a layer of metallic material on gate electrode 115c in contact opening 1640 to form gate contact via 167, as shown in FIG. 3. In some embodiments, forming the layer of metallic material can include performing a CVD process using dodecacarbonyl triruthenium (Ru₃(CO)₁₂, DCR) as a precursor to deposit Ru on the exposed surfaces of gate electrode 115c. In some embodiments, other precursors can be used to deposit other metals (e.g., Ir, Co, W, Cu, and/or Mo) in contact opening 1640. In some embodiments, the presence of SAM 369 on side surfaces of contact opening 1640 can prevent the metallic material from being deposited on dielectric side surfaces of contact opening 1640 covered by SAM 369. In some embodiments, the deposition of the metallic material can stop once a top surface of gate contact via 167 is coplanar with top surfaces of SAM 369.

The embodiments described herein are directed to a structure of a semiconductor device and a method of forming the structure. The structure can include a dielectric layer on a field effect transistor. The structure can further include a gate contact structure through the dielectric layer and in contact with a gate structure of the field effect transistor. The gate contact structure can include a metal via in contact with a gate electrode of the gate structure. The metal via can include a metal with a low value of a product of resistivity and mean free path, such as ruthenium. An interface between the metal via and the gate electrode can be oxygen free. The gate contact structure can further include a passivation layer between the metal via and the dielectric layer. The method of forming the structure can include forming an opening through the dielectric layer to expose a top surface of the gate electrode and cleaning the top surface of the gate electrode to remove an oxide layer at the top surface of the gate electrode. The method can further include forming a layer of small molecule inhibitor (SMI) at the top surface of the gate electrode exposed in the opening, forming the passivation layer on side surfaces of the opening, removing the layer of SMI, and deposit the metal via in the opening.

In some embodiments, a structure includes a substrate, a fin structure on the substrate, an S/D region on the fin structure, an S/D contact structure on the S/D region, a gate structure on the fin structure and adjacent to the S/D region, and a dielectric layer on the gate structure. The structure further includes a gate contact structure in the dielectric layer and on the gate structure. The gate contact structure includes a conductive layer in contact with the gate structure and a self-assembling monolayer (SAM) surrounding the conductive layer.

In some embodiments, a structure includes a transistor on a substrate. The transistor includes a channel region and a gate structure surrounding the channel region. The structure further includes dielectric layer on the transistor and a gate contact structure in the dielectric layer and on the gate structure. The gate contact structure includes ruthenium. An interface between the gate structure and the gate contact structure is oxygen-free.

In some embodiments, a method includes forming a fin structure on a substrate, forming a gate structure on the fin structure, depositing a dielectric layer on the gate structure, and forming a opening through the dielectric layer to expose a top surface of the gate structure. The method can further includes removing an oxide layer on the top surface of the gate structure, forming an inhibitor layer on the top surface of the gate structure, forming a passivation layer on side surfaces of the opening, and depositing a conductive layer in the opening.

It is to be appreciated that the Detailed Description section, and not the Abstract of the Disclosure section, is intended to be used to interpret the claims. The Abstract of the Disclosure section may set forth one or more but not all possible embodiments of the present disclosure as contemplated by the inventor(s), and thus, are not intended to limit the subjoined claims in any way.

The foregoing disclosure outlines features of several embodiments so that those skilled in the art may better understand the aspects of the present disclosure. Those skilled in the art will appreciate that they may readily use the present disclosure as a basis for designing or modifying other processes and structures for carrying out the same purposes and/or achieving the same advantages of the embodiments introduced herein. Those skilled in the art will also realize that such equivalent constructions do not depart from the spirit and scope of the present disclosure, and that they may make various changes, substitutions, and alterations herein without departing from the spirit and scope of the present disclosure.

What is claimed is:

1. A structure, comprising:
a substrate;
a fin structure on the substrate;
a source/drain (S/D) region on the fin structure;
an S/D contact structure on the S/D region;
a gate structure on the fin structure and adjacent to the S/D region;
a dielectric layer on the gate structure; and
a gate contact structure in the dielectric layer and on the gate structure, wherein the gate contact structure comprises:
a conductive layer in contact with the gate structure; and
a self-assembling monolayer (SAM) surrounding the conductive layer.

2. The structure of claim 1, wherein the SAM separates the conductive layer and the dielectric layer.

3. The structure of claim 1, wherein the conductive layer comprises ruthenium.

4. The structure of claim 1, wherein a ratio of a width of a top surface of the conductive layer to a width of a bottom surface of the conductive layer is between about 1 and about 3.

5. The structure of claim 1, wherein an atomic percentage of oxygen at an interface between the conductive layer and the gate structure is less than about 3.5%.

6. The structure of claim 1, wherein the SAM comprises dimethylamino-trimethylsilane (TMSDMA) or hexamethyldisilazane (HMDS).

7. The structure of claim 1, wherein a product of a resistivity of the conductive layer and an electron mean free path in the conductive layer is less than about 400 μΩ·μm².

8. A structure, comprising:
a transistor on a substrate, wherein the transistor comprises:
a channel region; and
a gate structure surrounding the channel region;
a dielectric layer on the transistor; and
a gate contact structure in the dielectric layer and on the gate structure, wherein:
the gate contact structure comprises ruthenium; and
an interface between the gate structure and the gate contact structure is oxygen-free.

9. The structure of claim 8, wherein the gate contact structure comprises a metal via and a self-assembling monolayer (SAM) between the metal via and the dielectric layer.

10. The structure of claim 8, wherein an aspect ratio of the gate contact structure is between about 5:1 and about 20:1.

11. The structure of claim 8, wherein a width of the gate contact structure is between about 2 nm and about 40 nm.

12. The structure of claim 8, wherein the gate structure comprises titanium nitride.

13. The structure of claim 8, wherein the transistor further comprises a source/drain (S/D) region, wherein the structure further comprises an S/D contact structure through the dielectric layer and in contact with the S/D region, and wherein the S/D contact structure comprises tungsten.

14. A method, comprising:
forming a fin structure on a substrate;
forming a gate structure on the fin structure;
depositing a dielectric layer on the gate structure;
forming a opening through the dielectric layer to expose a top surface of the gate structure;
removing an oxide layer on the top surface of the gate structure;
forming an inhibitor layer on the top surface of the gate structure;
forming a passivation layer on side surfaces of the opening; and
depositing a conductive layer in the opening.

15. The method of claim 14, wherein removing the oxide layer comprises performing an atomic layer etching process.

16. The method of claim 14, wherein forming the inhibitor layer comprises depositing a layer of pyridine on the top surface of the gate structure without covering the side surfaces of the opening with the layer of pyridine.

17. The method of claim 14, wherein forming the passivation layer comprises depositing a layer of dimethylamino-trimethylsilane (TMSDMA) to cover the side surfaces of the opening without covering the inhibitor layer with the TMSDMA.

18. The method of claim 14, wherein depositing the conductive layer comprises:
removing the inhibitor layer; and
depositing, after removing the inhibitor layer, a layer of ruthenium in the opening.

19. The method of claim 18, wherein depositing the layer of ruthenium comprises performing a chemical vapor deposition using dodecacarbonyl triruthenium as a precursor.

20. The method of claim 14, wherein depositing the conductive layer comprises forming an oxygen-free interface between the conductive layer and the gate structure.
